(19) United States
(12) Patent Application Publication
(10) Pub. No.: US 2024/0290848 A1
(43) Pub. Date: Aug. 29, 2024

(54) NANOCAVITY-BASED ELECTRODE AND CMOS-BASED DEVICE INCLUDING THE SAME

(71) Applicant: SAMSUNG ELECTRONICS CO., LTD., Suwon-si (KR)

(72) Inventors: Carlos C.J ALCANTARA, Suwon-Si (KR); Chisung BAE, Suwon-si (KR); Kitae PARK, Suwon-si (KR); Mikyung KIM, Suwon-si (KR)

(73) Assignee: SAMSUNG ELECTRONICS CO., LTD., Suwon-si (KR)

(21) Appl. No.: 18/337,527

(22) Filed: Jun. 20, 2023

(30) Foreign Application Priority Data
Feb. 23, 2023 (KR) 10-2023-0024528

(51) Int. Cl. H01L 29/41; H01L 27/092

(52) U.S. Cl. CPC H01L 29/41; H01L 27/092

(57) ABSTRACT

A nanocavity-based electrode and a complementary metal-oxide-semiconductor-based device including the same are provided. In the nanocavity-based electrode, a single or a plurality of unit layers is stacked, and each unit layer includes a single or a plurality of nanocavities.

### CROSS-REFERENCE TO RELATED APPLICATIONS

This application claims the benefit under 35 USC § 119(a) of Korean Patent Application No. 10-2023-0024528, filed on Feb. 23, 2023, in the Korean Intellectual Property Office, the entire disclosure of which is incorporated herein by reference for all purposes.

### BACKGROUND

### 1. Field

The following description relates to a nanocavity-based electrode and a complementary metal-oxide-semiconductor (CMOS)-based device including the same.

### 2. Description of Related Art

The exponential growth of machine learning applications since the last decade and its current ubiquity in our daily lives caused an unprecedented demand for memory capacity and bandwidth. As a result, Von Neumann-based architectures, based on which most modern computers have been built since the 1950s, are currently associated with performance bottleneck that makes it unsuitable for modern computing applications, such as high-performance and edge computing. Therefore, there is a growing and urgent need to develop new computing systems, semiconductor devices, and algorithms in a synergistic manner.

Cell recording can be performed through electrical or optical interfaces. While the latter provides theoretical advantages over the former, such as higher bandwidth, enhanced performance, and reduced parasitic effects, current optical technology still cannot compete, in terms of performance and high-throughput fabrication, with electrical-based approaches, which are supported by a vast and efficient ecosystem of design software vendors, IP developers, and manufacturing facilities. Therefore, the use of CMOS-based chips remains the only practical approach to be used in a development workflow where neuronal cell recordings are used for the development of new computing devices and algorithms.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, an electrode includes at least one of a single unit layer and a plurality of stacked unit layers, wherein each of the single unit layer or the plurality of stacked unit layers respectively comprises a single cavity or a plurality of cavities.

The cavities may be at least one of nanocavities and microcavities.

Each cavity of the single unit layer or each cavity the plurality of stacked unit layers may have a height of 1 nanometer (nm) to 1000 nm, a length of 1 nm to 1 millimeter (mm), or both.

For each of the single unit layer or each unit layer of the plurality of stacked unit layers, the cavities may be disposed between an upper surface of the unit layer and a lower surface of the unit layer facing the upper surface of the single unit layer.

The cavities of the single unit layer or the cavities of the plurality of stacked unit layers may be arranged in a row or arranged irregularly along a height direction of the electrode.

The unit layer of the single unit layer or the unit layers the plurality of the plurality of stacked unit layers may include a first insulating layer, a metal layer, and a second insulating layer.

The first insulating layer and the second insulating layer may respectively include insulating materials, and the cavities of the single unit layer or the cavities of the plurality of stacked unit layers may be formed in at least one or more portions of the metal layer, between the metal layer and the first insulating layer, or between the metal layer and the second insulating layer.

At least one of a single metal layer and a plurality of metal layers may be provided, and the single metal layer or the plurality of metal layers is embedded between the first insulating layer and the second insulating layer of each of the unit layer of the single unit layer or the unit layers of the plurality of stacked unit layers.

The plurality of stacked unit layers may be stacked to form a stepped stacked structure.

The plurality of stacked unit layers may be stacked such that diameters of the unit layers are continuously reduced.

The plurality of stacked unit layers include a unit layer having at least one or more shapes of a plate shape; or a circular shape, a semi-circular shape, an elliptical shape, a ring shape, or a truncated ring-shaped disc.

The unit layer further may include at least one or more active layers of a piezoelectric layer, a magnetoelectric layer, or a magnetostrictive layer.

The plurality of stacked unit layers may include metal layers having a same thickness or different thicknesses, and the plurality of stacked unit layers may include unit layers having a same thickness or different thicknesses.

The plurality of stacked unit layers may be stacked in a stacked structure in which a length of the metal layer of each unit layer is continuously reduced.

The plurality of stacked unit layers may be stacked in a stepped stacked structure in which a length of each unit layer and the length of the metal layer are continuously reduced.

The electrode may further include a single groove or a plurality of grooves disposed with an open side, wherein the groove or each of the plurality of grooves comprises a region, where at least a portion of the metal layer protrudes into the groove or the plurality of grooves, and wherein the region, where at least a portion of the metal layer protrudes into the groove or the plurality of grooves, has a stepped structure, in which a protruding length is continuously reduced, or has a same protruding length.

The single cavity or the plurality of cavities may be provided in a region close to the groove or the plurality of grooves, or the single cavity or the plurality of cavities may be exposed to an inner surface of the groove or the plurality of grooves.

The single cavity or the plurality of cavities formed between the upper surface of the unit layer and the lower surface of the unit layer, facing the upper surface, may be exposed to the inner surface of the groove or the plurality of grooves.

A device includes a complementary metal-oxide-semiconductor (CMOS) chip and an electrode which are integrated.

The device may be monolithically integrated or heterogeneously integrated.

Other features and aspects will be apparent from the following detailed description, the drawings, and the claims.

### BRIEF DESCRIPTION OF DRAWINGS

FIG. 1A illustrates an example configuration of a cavity (e.g., nanocavity)-based electrode, in accordance with one or more embodiments.

FIG. 1B illustrates an example cross-section of a cavity (e.g., nanocavity)-based electrode, in accordance with one or more embodiments.

FIG. 2 illustrates an example scanning electron microscope (SEM) image of a cross-section of an electrode, in accordance with one or more embodiments.

FIG. 3 illustrates an example configuration of a cavity (e.g., nanocavity)-based electrode, in accordance with one or more embodiments.

FIG. 4A illustrates an example manufacturing process of a cavity (e.g., nanocavity)-based electrode, in accordance with one or more embodiments.

FIG. 4B illustrates an example manufacturing process of a cavity (e.g., nanocavity)-based electrode, in accordance with one or more embodiments.

FIG. 4C illustrates an example manufacturing process of a cavity (e.g., nanocavity)-based electrode, in accordance with one or more embodiments.

FIG. 4D illustrates an example manufacturing process of a cavity (e.g., nanocavity)-based electrode, in accordance with one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

As used herein, “A or B,” “at least one of A and B,” “at least one of A or B,” “A, B or C,” “at least one of A, B and C,” and “at least one of A, B, or C,” each of which may include any one of the items listed together in the corresponding one of the phrases, or all possible combinations thereof.

The same name may be used to describe an element included in the examples described above and an element having a common function. Unless otherwise mentioned, the descriptions of the examples may be applicable to the following examples and thus, duplicated descriptions will be omitted for conciseness.

Hereinafter, examples will be described in detail with reference to the accompanying drawings. When describing an example with reference to the accompanying drawings, like reference numerals refer to like elements and a repeated description related thereto will be omitted.

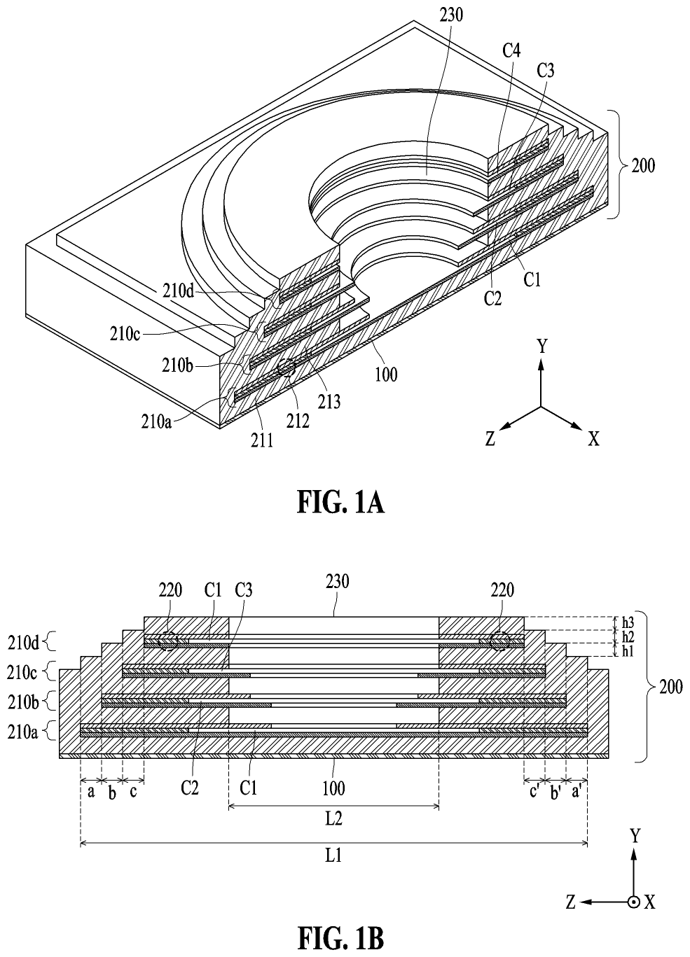

FIG. 1A illustrates an example configuration of a cavity (e.g., nanocavity)-based electrode, in accordance with one or more embodiments. FIG. 1B illustrates an example cross-section of a cavity (e.g., nanocavity)-based electrode, in accordance with one or more embodiments.

In an example, in an electrode 200, a single unit layer (e.g., n=1) or a plurality of (e.g., n>1) unit layers 210 (e.g., 210a, 210b, 210c, and 210d of FIGS. 1A and 1B) may be stacked.

In an example, the electrode 200 may include a single cavity or a plurality of cavities (e.g., C1, C2, C3, and C4 of FIGS. 1A and 1B) which may be included in an inner portion of the unit layer 210 (e.g., 210a, 210b, 210c, and 210d of FIGS. 1A and 1B), between the unit layer (e.g., 210a) and the unit layer (e.g., 210b), or both in the inner portion of the unit layer and between the unit layers. In some examples, the cavities (e.g., C1, C2, C3, and C4 of FIGS. 1A and 1B) may be nanocavities.

In an example, the electrode 200 may further include a substrate 100. In one or more non-limited examples, the substrate 100 may be a complementary metal-oxide-semiconductor (CMOS) chip.

In an example, a height of each of the cavities (e.g., nanocavities, C1, C2, C3, and C4 of FIGS. 1A and 1B) may be approximately 1 nanometer (nm) to approximately 1000 nm; approximately 1 nm to 950 nm; 1 nm to approximately 900 nm; approximately 1 nm to approximately 800 nm; approximately 1 nm to approximately 750 nm; approximately 1 nm to approximately 700 nm; approximately 1 nm to approximately 600 nm; approximately 1 nm to approximately 500 nm; approximately 1 nm to approximately 400 nm; approximately 1 nm to approximately 300 nm; approximately 1 nm to approximately 200 nm; approximately 1 nm to approximately 150 nm; approximately 1 nm to approximately 100 nm; approximately 1 nm to approximately 90 nm; approximately 1 nm to approximately 80 nm; approximately 1 nm to approximately 70 nm; approximately 1 nm to approximately 60 nm; approximately 1 nm to approximately 50 nm; approximately 1 nm to approximately 40 nm; approximately 1 nm to approximately 30 nm; approximately 1 nm to approximately 20 nm; approximately 1 nm to approximately 10 nm; approximately 1 nm to approximately 5 nm; approximately 2 nm to approximately 10 nm; approximately 2 nm to approximately 20 nm; approximately 2 nm to approximately 70 nm; approximately 2 nm to approximately 100 nm; or approximately 3 nm to approximately 100 nm.

In an example, a diameter (or a length) of each of the cavities (e.g., nanocavities, C1, C2, C3, and C4 of FIGS. 1A and 1B) may be approximately 1 nm or more; approximately 10 nm or more; approximately 20 nm or more; approximately 30 nm or more; approximately 50 nm or more; approximately 80 nm or more; approximately 100 nm or more; approximately 150 nm or more; approximately 200 nm or more; approximately 300 nm or more; approximately 400 nm or more; approximately 500 nm or more; approximately 600 nm or more; approximately 800 nm or more; approximately 1000 nm or more; approximately 1.5 micrometers (μm) or more; approximately 2 μm or more; approximately 3 μm or more; approximately 5 μm or more; approximately 10 μm or more; approximately 20 μm or more; approximately 50 μm or more; approximately 80 μm or more; approximately 100 μm or more; approximately 200 μm or more; approximately 300 μm or more; approximately 500 μm or more; approximately 600 μm or more; approximately 800 μm or more; approximately 900 μm or more; approximately 1 millimeter (mm) or more; approximately 1 nm or less; approximately 10 nm or less; approximately 20 nm or less; approximately 30 nm or less; approximately 50 nm or less; approximately 80 nm or less; approximately 100 nm or less; approximately 150 nm or less; approximately 200 nm or less; approximately 300 nm or less; approximately 400 nm or less; approximately 500 nm or less; approximately 600 nm or less; approximately 800 nm or less; approximately 1000 nm or less; approximately 1.5 μm or less; approximately 2 μm or less; approximately 3 μm or less; approximately 5 μm or less; approximately 10 μm or less; approximately 20 μm or less; approximately 50 μm or less; approximately 80 μm or less; approximately 100 μm or less; approximately 200 μm or less; approximately 300 μm or less; approximately 500 μm or less; approximately 600 μm or less; approximately 800 μm or less; approximately 900 μm or less; or approximately 1 mm or less. In some examples, the diameter (or the length) of each of the cavities (e.g., nanocavities, C1, C2, C3, and C4 of FIGS. 1A and 1B) may be approximately 1 nm to approximately 1 mm.

In an example, when the cavities have the height and diameter in the ranges described above, impedance may be reduced, and a spatial resolution, a contact area, and the like may be increased.

In an example, the cavities (e.g., nanocavities, C1, C2, C3, and C4 of FIGS. 1A and 1B) may have the same or different heights and diameters in the plurality of unit layers.

Referring to FIGS. 1A and 1B, in one or more examples, the cavities (e.g., nanocavities, C1, C2, C3, and C4 of FIGS. 1A and 1B) having the same or different heights may be arranged along a height direction. In one or more examples, the cavities (e.g., nanocavities, C1, C2, C3, and C4 of FIGS. 1A and 1B) having the same height may be arranged in a row or irregularly along the height direction (e.g., a y direction).

In an example, the cavities (e.g., nanocavities, C1, C2, C3, and C4 of FIGS. 1A and 1B) may be implemented by introducing a material (e.g., electrodeposition of platinum black or metal-organic framework deposition) into the cavities (e.g., nanocavities). In one or more examples, the material may be deposited on upper and lower surfaces of the cavity (e.g., nanocavity).

In an example, the unit layer 210 (e.g., 210a, 210b, 210c, and 210d of FIGS. 1A and 1B) may have at least one or more shapes of, as only examples, a plate shape; a circular shape, a semi-circular shape, an elliptical shape, a ring shape, or a truncated ring-shaped disc, or a combination thereof. For example, the plate-shaped unit layer may be a polygonal (e.g., triangular, rectangular, square, hexagonal, trapezoidal, rhombic, etc.) sheet, film, or thin film. In an example, the plurality of unit layers 210 (e.g., 210a, 210b, 210c, and 210d of FIGS. 1A and 1B) may include unit layers having the same or different shapes. In an example, referring to FIG. 1A, regarding the plurality of unit layers, a unit layer having a plate shape; and a unit layer having a ring shape or truncated ring-shaped disc may be sequentially stacked.

In an example, the unit layer 210 (e.g., 210a, 210b, 210c, and 210d of FIGS. 1A and 1B) may include a first insulating layer 211; a metal layer 212 positioned on at least a portion of the first insulating layer 211; and a second insulating layer 213.

In an example, the first insulating layer 211 and the second insulating layer 213 may include respective insulating materials. In a non-limiting example, the first insulating layer 211 and the second insulating layer 213 may have the same or different thicknesses, diameters, or both. In some examples, the thicknesses of the first insulating layer 211 and the second insulating layer 213 may be, respectively, approximately 1 nm to approximately 800 nm; approximately 1 nm to approximately 750 nm; approximately 1 nm to approximately 700 nm; approximately 1 nm to approximately 650 nm; approximately 1 nm to approximately 600 nm; approximately 1 nm to approximately 500 nm; approximately 1 nm to approximately 400 nm; approximately 1 nm to approximately 300 nm; approximately 1 nm to approximately 200 nm; approximately 1 nm to approximately 250 nm; approximately 1 nm to approximately 200 nm; approximately 1 nm to approximately 150 nm; approximately 1 nm to approximately 120 nm; approximately 1 nm to approximately 100 nm; approximately 1 nm to approximately 90 nm; approximately 1 nm to approximately 70 nm; approximately 1 nm to approximately 50 nm; approximately 1 nm to approximately 30 nm; approximately 1 nm to approximately 20 nm; approximately 1 nm to approximately 15 nm; approximately 1 nm to approximately 10 nm; approximately 1 nm to approximately 8 nm; approximately 1 nm to approximately 5 nm; approximately 2 nm to approximately 20 nm; or approximately 2 nm to approximately 10 nm. In some examples, the thickness of the first insulating layer 211, the second insulating layer 213, or both may be the same as or different from the thickness of the metal layer 212.

In some examples, the thickness of the first insulating layer 211, the second insulating layer 213, or both may be thinner or thicker than the thickness of the metal layer.

In an example, the first insulating layer 211 and the second insulating layer 213 may include an insulating material, and the first insulating layer 211 and the second insulating layer 213 may be single or multiple layers, respectively. In some examples, the insulating material may include at least one or more of an oxide-nitride-oxide (ONO) film (e.g., ONONO), an silicon-on insulator, zinc sulfide (ZnxSy), aluminum oxide (AlxOy) (e.g., Al₂O₃), hafnium oxide (HfxOy), molybdenum oxide (MoxOy), titanium oxide (TixOy), titanium nitride (TiN), tungsten oxide (WxOy), silicon carbide (SiCx), silicon oxide (SiOx), silicon nitride (SixNy), silicon nitride (SiOxNy), indium oxide (InxOy), tin oxide (SnxOy), or zinc oxide (ZnxOy), or a combination thereof (herein, x and y each may be a rational number greater than 0 and equal to or smaller than 6). In some examples, the insulating material may include an Oxide-Nitride-Oxide (ONO) film (e.g., ONONO). In some examples, the first insulating layer 211 and the second insulating layer 213 may include the same or different insulating materials. In some examples, the first insulating layer 211 and the second insulating layer 213 may surround a metal layer 212, or the metal layer 212 may be embedded in a unit layer.

In an example, the metal layer 212 may provide a conductive electrode operation, and any conductive material may be applied thereto without limitation. In some examples, the metal layer may include at least one of Cu, Co, Ir, Ta, In, Cr, Mn, Mo, Tc, W, Re, Fe, Sc, Ti, Sn, Ge, Sb, Al, Ag, Pt, Ni, or Au or a combination thereof. However, the examples are not limited thereto. In some examples, the metal layer may include at least one or more of a metal, an oxide (e.g., indium tin oxide (ITO), indium gallium oxide (IGO), indium zinc oxide (IZO), or indium gallium zinc oxide (IGZO)) alloy, or intermetallic compound or a combination thereof. In some examples, the metal layer may further include a conductive organic material. In some examples, the metal layer may be mixed with the conductive organic material or may include a conductive organic material layer. In some examples, the conductive organic material may include at least one or more of a carbon nanotube (CNT), graphene, or a conductive polymer. The conductive polymer may be poly(3,4-ethylenedioxythiophene)/poly(4-styrene sulfonate (PEDOT/PSS), polyaniline (PANI), polypyrrole (PPy), polythiophene (PT), polyacetylene (PA), poly para-phenylene vinylene (PPV), polyparaphenylene (PPP), (SN)x(Poly sulfur nitride), or the like. However, the examples are not limited thereto.

In some examples, the metal layer may include Cu/Au/Mn, Pt/Bi/Co, Cu/Co/Au/Pt, or Pt/Co/Au/Se/Cu/Fe.

In an example, the metal layer 212 may include a single or a plurality of metal layers including the same or different metals.

In an example, a thickness of the metal layer 212 may be approximately 40 nm or more; approximately 50 nm or more; approximately 70 nm or more; approximately 80 nm or more; approximately 100 nm to approximately 400 nm; approximately 100 nm to approximately 380 nm; approximately 100 nm to approximately 350 nm; approximately 100 nm to approximately 300 nm; approximately 100 nm to approximately 280 nm; approximately 100 nm to approximately 260 nm; approximately 100 nm to approximately 250 nm; approximately 100 nm to approximately 230 nm; approximately 100 nm to approximately 200 nm; approximately 100 nm to approximately 180 nm; approximately 100 nm to approximately 150 nm; approximately 100 nm to approximately 130 nm; or approximately 100 nm to approximately 110 nm. In some examples, the plurality of unit layers may include metal layers having the same or different thicknesses, respectively. In some examples, the plurality of unit layers may be stacked in such a way that a diameter (or a length) of the metal layer decreases. In some examples, the plurality of unit layers may be formed in a stepped stacked structure in which the diameter (or the length, L1 of FIG. 1B) of the metal layer decreases by predetermined values (e.g., a, b, c, a′, b′, and c′ of FIG. 1B).

In an example, the cavities (e.g., nanocavities C1, C2, C3, and C4 of FIGS. 1A and 1B) may be formed on at least one portion or more of an inner portion of the metal layer 212, between the metal layer 212 and the first insulating layer 211, or between the metal layer 212 and the second insulating layer 213.

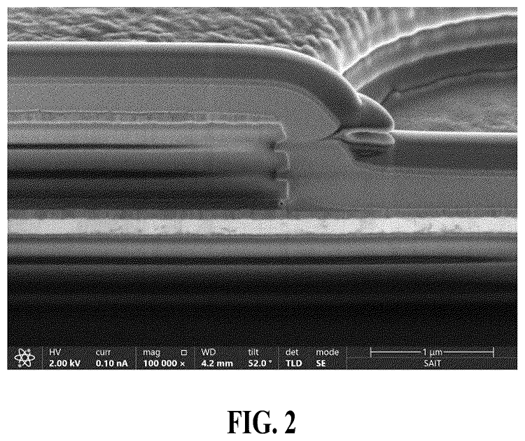

According to an example, the metal layer 212 may include a first metal layer and a second metal layer, and may include cavities (e.g., nanocavities C1, C2, C3, and C4 of FIGS. 1A and 1B) between the first metal layer and the second metal layer. In some examples, the metal layer 212 may include a region 220 where cavities are not formed. In some examples, the metal layer 212 may include a first metal layer, a second metal layer, and a third metal layer, and may include cavities (e.g., nanocavities) between the first metal layer and the second metal layer, between the second metal layer and the third metal layer, or both. FIG. 2 illustrates an example of a scanning electron microscope (SEM) image of a cross-section of the electrode, and referring to FIG. 2, nanocavities formed between metal layers of the electrode may be observed.

In an example, the unit layer 210 (e.g., 210a, 210b, 210c, and 210d of FIGS. 1A and 1B) may further include at least one or more active layers of a piezoelectric layer (e.g., AlN), a magnetoelectric layer, or a magnetostrictive layer. In some examples, the active layer may provide a mechanical stimulus. In some examples, the cavities (e.g., nanocavities) may be formed between the active layers. In some examples, the active layer may be formed on at least one or more of the inside, upper end, or the lower end of the metal layer 212.

In an example, the electrode 200 may be implemented using different combinations of materials (e.g., iridium oxide, aluminum nitride, and bismuth selenide, as only examples) and used for different purposes, such as, but not limited to, current injection, voltage recording, pH measurement, and temperature sensing.

In an example, a thickness of the unit layer 210 (e.g., 210a, 210b, 210c, and 210d of FIGS. 1A and 1B) may be approximately 1 nm or more; approximately 10 nm or more; approximately 20 nm or more; approximately 50 nm or more; approximately 80 nm or more; approximately 100 nm or more; approximately 200 nm or more; approximately 300 nm or more; approximately 500 nm or more; approximately 1000 nm or more; approximately 1 nm to approximately 10 mm; approximately 1 nm to approximately 1 mm; approximately 1 nm to approximately 0.1 mm; approximately 1 nm to approximately 0.01 mm; approximately 500 nm to approximately 0.01 mm; or approximately 800 nm to approximately 0.01 mm. In some examples, the plurality of unit layers may have the same or different thicknesses. In some examples, the plurality of unit layers may have a reduced diameter (or length) to form a stepped stacked structure.

In some examples, the plurality of unit layers may be reduced or separated by spacings of a, b, c, a′, b′, and c′ of FIG. 1B. In non-limited examples, each of the spacings a, b, c, a′, b′, and c′ of FIG. 1B may be approximately 1 nm or more; approximately 5 nm or more; approximately 10 nm or more; approximately 20 nm or more; approximately 30 nm or more; approximately 50 nm or more; approximately 100 nm or more; approximately 200 nm or more; approximately 500 nm or more; approximately 800 nm or more; approximately 1 μm or more; approximately 30 μm or less; approximately 20 μm or less; approximately 10 μm or less; approximately 5 μm or less; approximately 1 μm or less; approximately 100 nm to approximately 30 μm; approximately 100 nm to approximately 20 μm; approximately 100 nm to approximately 10 μm; approximately 500 nm to approximately 5 μm; or approximately 500 nm to approximately 2 μm.

In an example, the plurality of unit layers 210 (e.g., 210a, 210b, 210c, and 210d of FIGS. 1A and 1B) may be stacked in a stepped stacked structure in which at least a portion of the electrode has a multi-level structure. In some examples, heights (e.g., h1, h2, and h3 of FIG. 1B) of the multi-levels in the stepped stacked structure may be the same or different. In some examples, the unit layers 210 (e.g., 210a, 210b, 210c, and 210d of FIGS. 1A and 1B) may be stacked in the stacked structure in which the diameter of each unit layer is continuously reduced. In some examples, the unit layers 210 (e.g., 210a, 210b, 210c, and 210d of FIGS. 1A and 1B) may be stacked in the stacked structure in which the diameter of the metal layer of each unit layer is continuously reduced. In some examples, the plurality of unit layers 210 (e.g., 210a, 210b, 210c, and 210d of FIGS. 1A and 1B) may be stacked in the stepped stacked structure in which the length (or the diameter) of each unit layer and the length (or the diameter) of the metal layer are continuously reduced. In some examples, n unit layers (herein, n is an integer of 1 or more) having the same length (or diameter) and thickness may be stacked, and the diameter of the metal layer 212 at this time may be constantly reduced. The stepped multi-levels may be formed by reducing diameters of unit layers subsequent to an n-th layer, and the diameter of the metal layer 212 at this time may be constantly reduced.

Referring to FIG. 1A, the plurality of unit layers 210 (e.g., 210a, 210b, 210c, and 210d of FIGS. 1A and 1B) having the same diameter may be stacked, and the stepped multi-levels may be formed by continuously reducing the diameters of the unit layers subsequent to the n-th layer. In some examples, the diameter of the metal layer within the unit layer may be continuously reduced. In some examples, the thicknesses of the unit layers may be the same or different. In some examples, the thicknesses of the metal layers 212 may be the same or different. In some examples, the unit layers having the same thickness may be stacked and the unit layers subsequent to the n-th layer may be stacked so that the diameter thereof (e.g., L1 of FIG. 1B) is constantly (e.g., by spacings of a, b, c, a′, b′, and c′ of FIG. 1B) reduced.

In an example, the electrode may include a single or a plurality of grooves 230, and the grooves may expose a side surface of the electrode.

In an example, the grooves 230 may expose cavities (e.g., nanocavities) of the plurality of stacked unit layers 210 (e.g., 210a, 210b, 210c, and 210d of FIG. 1A). In an example, the grooves 230 may include cavities (e.g., nanocavities) in a region close to the grooves 230 or may have cavities (e.g., nanocavities) exposed in the groove 230.

In an example, the grooves 230 may expose the nanocavities formed in the metal layer 212 of the plurality of stacked unit layers. In an example, the grooves 230 may expose the cavities (e.g., nanocavities) formed between unit layers of the plurality of stacked unit layers. In some examples, an inner surface of the grooves 230 may include cavities (e.g., nanocavities) formed between an upper surface of the unit layer and a lower surface of the unit layer, facing the lower surface, or may include cavities (e.g., nanocavities, C1, C2, C3, and C4 of FIGS. 1A and 1B) formed in the metal layer 212 in the unit layer.

In an example, the grooves 230 may include a region where at least a portion of the metal layer 213 protrudes, and the region with the protruding metal layer may protrude from an inner wall of the groove. In some examples, the metal layer 213 in at least a portion of the plurality of unit layers may protrude. In some examples, a single or a plurality of metal layers 213 may protrude. In some examples, a plurality of regions with the protruding metal layer may have a stepped structure, in which a protruding length (e.g., an X-axis direction of FIG. 1A) is continuously reduced (e.g., along a Y-axis direction of FIG. 1A) or may have the same protruding length.

In a non-limited example, the grooves 230 may include a polygonal columnar shape, circular column shape, or both. In some examples, the grooves 230 may include a cut polygonal columnar shape, circular column shape, or both.

In an example, a diameter (L2 of FIG. 1B) of the groove 230 may be approximately 100 nm to approximately 100 μm; approximately 100 nm to approximately 90 μm; approximately 100 nm to approximately 80 μm; approximately 100 nm to approximately 70 μm; approximately 100 nm to approximately 60 μm; approximately 100 nm to approximately 50 μm; approximately 100 nm to approximately 40 μm; approximately 100 nm to approximately 30 μm; approximately 100 nm to approximately 20 μm; approximately 100 nm to approximately 10 μm; approximately 1 μm to approximately 10 μm; approximately 100 nm to approximately 5 μm; approximately 100 nm to approximately 3 μm; approximately 100 nm to approximately 1 μm; approximately 100 nm to approximately 900 nm; approximately 100 nm to approximately 800 nm; approximately 100 nm to approximately 700 nm; approximately 100 nm to approximately 600 nm; approximately 100 nm to approximately 500 nm; approximately 100 nm to approximately 400 nm; approximately 100 nm to approximately 300 nm; approximately 100 nm to approximately 250 nm; or approximately 100 nm to approximately 200 nm.

In an example, the CMOS-based device may be a device in which a CMOS chip and the electrode of the examples are integrated. In an example, a single or a plurality of electrodes may be arranged on the CMOS chip. In some examples, the CMOS-based device may be device in which the cavity (e.g., nanocavity)-based electrode and the CMOS chip are monolithically integrated on the CMOS chip. In some examples, the CMOS-based device may be a heterogeneous integration device of the nanocavity-based electrode and the CMOS chip.

In an example, the CMOS-based device may be implemented as electrochemical sensors, miniaturized environmental sensors, electrode for water splitting, supercapacitors, drug delivery devices, or electronic skin for robotics. However, these are only examples, and the CMOS-based device may be implemented in other environments.

In an example, the CMOS-based device may be a device for electrochemical sensing applications such as pH, dopamine, environmental, or glucose sensing, as only examples.

In an example, the CMOS-based device may be a device for water splitting (e.g., photoelectrochemical water splitting) applications or energy storage applications, as only examples.

In an example, the CMOS-based device may be a device for drug delivery and drug screening applications, as only examples.

In an example, the CMOS-based device may be a device for electronic skin applications, as only an example.

In an example, the nanocavities may be stacked with conductive electrodes of the electrode, thereby further reducing the impedance by up to two times (per unit layer).

In an example, the electrode may correspond to a three-dimensional (3D) multi-level nanocavity device, and may individually control each unit layer of the electrode. In non-limited examples, in a 4-level electrode, a first unit layer may provide current injection, a second unit layer may provide voltage recording, a third unit layer may provide temperature measurement, and a fourth unit layer may provide voltage bias. However, these are only examples, and the first unit layer, the second unit layer, the third unit layer, and the fourth unit layer may provide different operations.

The CMOS-based device may be implemented as a sensing layer for real-time action potential recording of biological cells. In some examples, the CMOS-based device may sense, as only examples, pH, glucose, triglyceride, or mRNA. However, the examples are not limited thereto.

An example electronic device including the CMOS-based device of the examples may be provided. In examples, the electronic device may include a sensor, an energy production or storage device, or the like, or may be all or a portion of a biomimetic robot.

According to an example, the cavity (e.g., nanocavity)-based electrode may have compatibility with a CMOS chip, and the introduction of a material or an additional operational layer (e.g., a conductive layer) may be implemented according to the purpose. In an example, the cavity (e.g., nanocavity)-based electrode may be used for measurement or control of ex vivo or in vivo electrochemical signals, biomimetic materials (e.g., electronic skin for robotics), bio-implant devices, drug delivery medium, and the generation or storage of photoelectrochemical energy (e.g., electrodes for water splitting or supercapacitors).

The CMOS-based device may be applied to various electrochemical sensing applications by reducing impedance or increasing specific capacitance.

In an example, when the electrode is configured such that the plurality of (e.g., approximately 50 layers (n=50)) unit layers are stacked, electrical impedance or specific capacitance may be improved by approximately two times.

In an example, the electrode may provide a small footprint and high compatibility with CMOS manufacturing. In an example, as a proof-of-principle device, a 128-channeled chip is being manufactured with a 4-level electrode (30 channels per level+8×GND). By stacking the electrodes, the electrical impedance may be significantly reduced without enlarging the device footprint.

In an example, the electrode may independently control each level/electrode stack (e.g., the unit layer) while interfacing with the same biological cell.

In an example, the electrode may be implemented using different combinations of various materials (e.g., iridium oxide, aluminum nitride, and bismuth selenide) of each unit layer, and may be used for different purposes, such as, but not limited to, current injection, voltage recording, pH measurement, and temperature sensing. It may affect spatial resolution, since each electrode stack remains buried under the same aperture, which is much smaller than biological cells.

In an example, the electrode may implement a partially free-standing electrode stack by laterally wet-etching the insulating layer during a cavity enlargement fabrication step of minimizing a parasitic effect.

In an example, a lateral space between the electrodes may enable cell expansion into the corresponding region, thereby increasing sealing resistance and maximizing a signal-to-noise ratio.

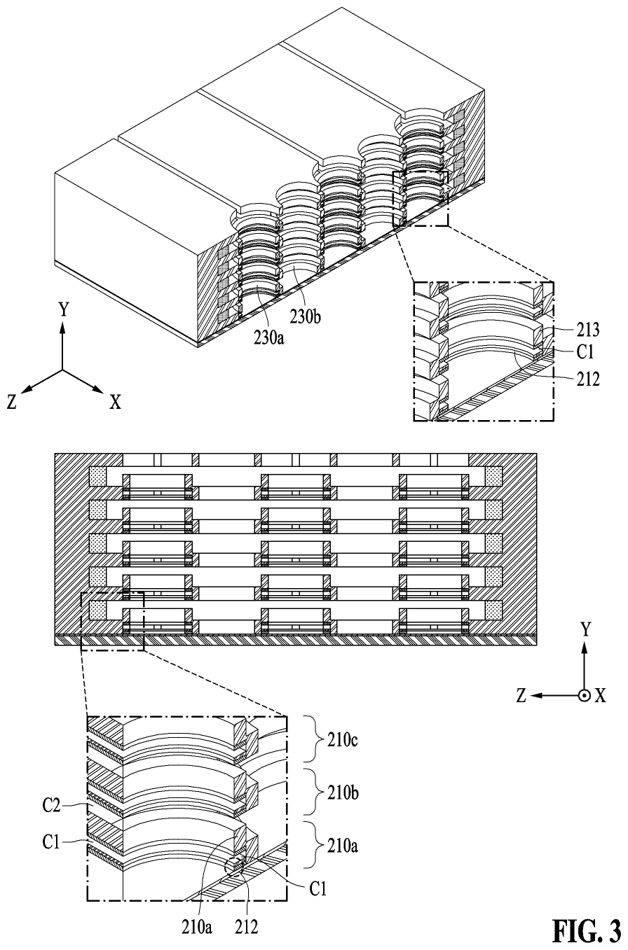

Referring to FIG. 3, a multilayer cavity (e.g., nanocavity, C1, 230a of FIG. 3) and a multilayer cavity (e.g., nanocavity, C2, 230b of FIG. 3) having a concentric stack of a CMOS interface thin film may be provided. The multilayer cavity (e.g., nanocavity, C1 of FIG. 3) may include a conductive layer (e.g., Au) for cell recording, electroporation, and local heating, a piezoelectric layer (e.g., AlN) for mechanical excitation, or a magnetic layer for manipulating magnetic nanoparticles to trigger cell activity.

In an example, the cavity (e.g., nanocavity, C1 of FIG. 3) may induce connection between the unit layers on the same level. The cavity (e.g., nanocavity, C2 of FIG. 3) may be a gap formed between each metal stack throughout the entire length of the electrode.

In an example, the multilayer cavity (C1, 230a of FIG. 3) may provide various operations according to the purpose of the electrode. In some examples, referring to FIG. 3, the multilayer cavity (C1, 230a of FIG. 3) may provide optical coupling for cell recording and excitation, chemical coupling for microfluidic interfaces, and opening of pathways between cavities to enable 3D cell culturing and fluid exchange.

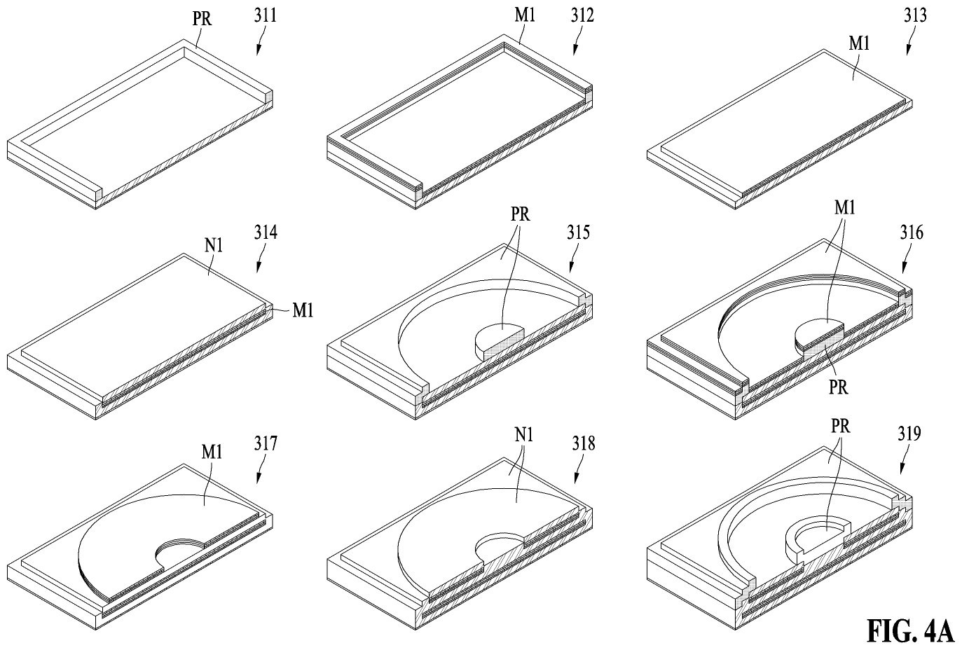

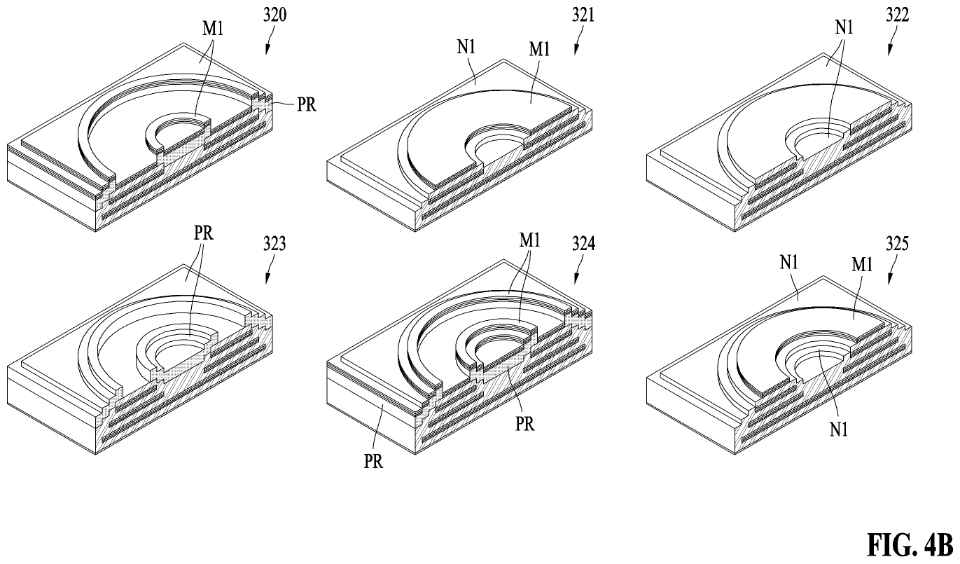

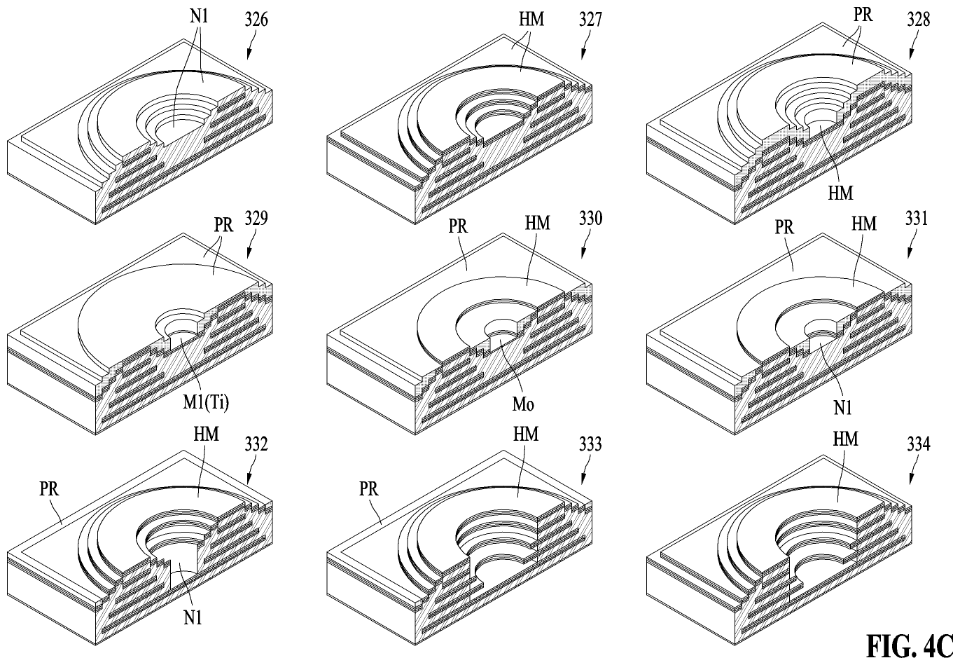

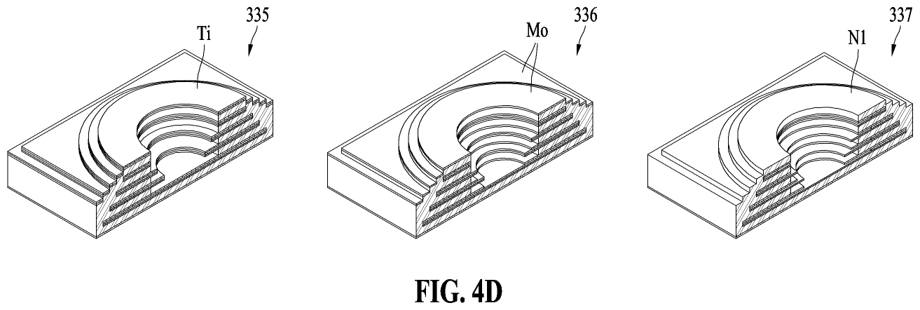

Referring to FIGS. 4A to 4D, in a method of manufacturing an electrode, a plurality of unit layers, which are n or more unit layers, may be sequentially stacked by repeatedly applying a stacking process including the steps of patterning a photoresist on an insulating layer, depositing an active layer including a sacrificial layer, removing the photoresist, forming an insulating layer on the active layer, patterning a photoresist on the insulating layer, depositing a metal layer including a sacrificial layer, removing the photoresist, and forming an insulating layer on the active layer. Next, the process may proceed to a step of forming a cavity (e.g., a nanocavity). A step of etching may include the steps of forming a hard mask, and etching the hard mask. In the step of etching, a cavity (e.g., nanocavity) may be formed by etching the hard mask, the sacrificial layer, or the insulating layer.

In an example, in the method of manufacturing the electrode of the disclosure, an electrode may be formed by implementing at least one or more of the number of unit layers to be stacked, an area, shape, and thickness of the metal layer, a diameter of an aperture, or a height of the cavity (e.g., nanocavity) (e.g., a thickness of the sacrificial layer).

Referring to FIGS. 4A to 4D, the method may include step 311 of patterning a photoresist PR, step 312 of depositing a metal layer M1 including a sacrificial layer, step 313 of removing the photoresist PR, step 314 of forming an insulating layer N1 on the metal layer M1, step 315 of patterning a photoresist PR on the insulating layer N1, step 316 of depositing a metal layer M1 including a sacrificial layer, step 317 of removing the photoresist PR, step 318 of depositing an insulating layer N1 on the metal layer M1, step 319 of patterning a photoresist PR, step 320 of depositing a metal layer M1 including a sacrificial layer, step 321 of removing the photoresist PR, step 322 of depositing an insulating layer N1, step 323 of patterning a photoresist PR, step 324 of depositing a metal layer M1 including a sacrificial layer, step 325 of removing the photoresist PR, step 326 of depositing an insulating layer N1, step 327 of forming a hard mask HM, step 328 of patterning a photoresist PR, step 329 of etching the hard mask HM, step 330 of etching the hard mask HM, step 331 of etching the hard mask HM, step 332 of performing dry etching of the insulating layer N1, step 333 of performing wet etching of the insulating layer N1, step 334 of removing the photoresist PR, step 335 of etching the hard mask HM, step 336 of etching the hard mask HM, and step 337 of etching the hard mask HM.

In an example, the sacrificial layer may include silicon nitride, chromium, copper, or tungsten, and may include a single layer or a plurality of layers. In some examples, a thickness of the sacrificial layer may control the thickness (or the height) of the cavity (e.g., nanocavity). According to an example, a thickness of the insulating layer N1 may be controlled according to manufacturing methods.

In some examples, a layer that is thinner than the metal layer may be used by a conformal method (e.g., atomic layer deposition (ALD)). In some examples, the thickness of the insulating layer may be thicker than the thickness of the metal layer by a non-conformal method (e.g., plasma enhanced chemical vapor deposition (PECVD)).

In an example, the metal layer M1 including the sacrificial layer may include the conductive material layer described above with reference to FIG. 1A. In some examples, the metal layer M1 may further include at least one or more of a piezoelectric layer, a magnetoelectric layer, and a magnetostrictive layer on the inside of the metal layer M1, a surface thereof, or both.

In step 327 of forming the hard mask HM, a hard mask including a sacrificial layer may be formed, and in some examples, a Mo/Ti/SiO₂ hard mask may be formed.

In step 329 of etching the hard mask, SiO₂ in the hard mask may be etched (e.g., dry etching).

In step 330 of etching the hard mask, Ti in the hard mask may be etched (e.g., dry etching).

In step 331 of etching the hard mask, Mo in the hard mask may be etched (e.g., dry etching).

In step 332 of performing the dry etching of the insulating layer N1, and in step 333 of performing the wet etching of the insulating layer N1, the configuration (e.g., the area, shape, or structure) of the groove may be implemented.

In step 324 of removing the photoresist, the remaining photoresist may be removed.

In step 335 of etching the hard mask, SiO₂ in the hard mask may be etched (e.g., dry etching).

In step 336 of etching the hard mask, Ti in the hard mask may be etched (e.g., dry etching).

In step 337 of etching the hard mask, Mo in the hard mask may be etched (e.g., dry etching and wet etching).

With regard to the term “deposition” as disclosed herein, the deposition process which is well known in the technical field of the disclosure may be used, and for example, a typical deposition process (e.g., a metal layer), such as, but not limited to, sputtering, thermal evaporation, e-beam evaporation, atomic layer deposition, chemical vapor deposition (CVD), low pressure chemical vapor deposition, physical vapor deposition (PVD), plasma enhanced chemical vapor deposition, thermal oxidation, laser sintering, localized electrodeposition, or metal ink deposition may be used. However, the examples are not limited thereto. In some examples, pulse electrodeposition may be performed by preparing electrolytes containing Cu and AU ions and switching a potential between V1 and V2. Cu and Au deposition herein may be deposited at a higher atomic percentage ratio, respectively, with a pulse width and frequency that define the thickness of each layer. Then, nanocavities may be formed by selectively etching (i.e., wet etching) Cu or Au. This process may be repeated for two or more active species (e.g., Cu—Au—Mn, Pt—Bi—Co, Cu—Co—Au—Pt, Pt—Co—Au—Se—Cu—Fe, etc.)

In the one or more examples, the photoresist may be patterned by using components, application methods, or patterning processes well known in the technical field of the one or more examples, and thus, details thereof will not be mentioned in the one or more examples.

In the one or more examples, for coating, a typical coating process, such as, but not limited to, spin coating, roll coating, spray coating, dip coating, flow coating, doctor blade, dispensing, and ink jet printing may be used. However, the examples are not limited thereto.

In the one or more examples, for the etching process, dry etching or wet etching may be used. In the wet etching, an etchant containing an acid may be used. In the dry etching, an etching gas or plasma (e.g., O2 plasma etching) may be used.

In the one or more examples, for the patterning process, a photomask, etching, or the like well-known in the technical field may be used, and thus, details thereof will not be mentioned in the disclosure.

In an example, in a method of manufacturing a CMOS-based device, the electrode and the CMOS chip of the one or more examples are integrated to manufacture a stand-alone device or are monolithically integrated on a pre-patterned wafer (e.g., the CMOS chip) to manufacture a device, and the device may be wire-bonded to a chip carrier, and may be sealed.

Free-standing vertical nanoprobes of the related art may not provide the recording of the same neuronal network successively, from viewpoints of production or development, and may be associated with electrochemically unstable coating (e.g., platinum black), short recording session, high electrochemical impedance, low electrode density, non-robust manufacturing processes, or non-scalable design. In addition, the free-standing structures may be more prone to mechanical damage and more susceptible to process variabilities, such as variable height, diameter, and surface properties within the same device. In an example, protruding surfaces, such as vertical nanoprobes (e.g., nanostraws or nanowires) with a high aspect ratio, may cause low stability, complicated manufacturing process, and poor reproducibility. As a result, dense arrays of nanostructures with a high aspect ratio are inherently associated with uneven surfaces and wettability gradients, which may considerably reduce the quality of an interface between nanoprobes and neuronal cells, such as by lowering sealing resistance.

In order to solve the problems of the related art, an electrode, in which a single or a plurality of unit layers is stacked, and each unit layer includes a single or a plurality of nanocavities is provided.

Each nanocavity may have a height of 1 nm to 1000 nm, a length of 1 nm to 1 mm, or both.

In an example, the electrode may further include cavities formed between an upper surface of the unit layer and a lower surface of the unit layer facing the upper surface.

In an example, the nanocavities may be arranged in a row or irregularly along a height direction of the electrode.

In an example, the unit layer may include a first insulating layer, a metal layer, and a second insulating layer.

In an example, the first insulating layer and the second insulating layer may include insulating materials, respectively, and the nanocavities may be formed in at least one or more portions of inside of the metal layer, between the metal layer and the first insulating layer, or between the metal layer and the second insulating layer.

In an example, a single or a plurality of metal layers may be provided, and the metal layer may be embedded between the first insulating layer and the second insulating layer.

In an example, the plurality of unit layers may be stacked to form a stepped stacked structure.

In an example, the plurality of unit layers may be stacked such that diameters of the unit layers are continuously reduced.

In an example, the plurality of unit layers may include a unit layer having at least one or more shapes of a plate shape; or a circular shape, semi-circular shape, elliptical shape, ring shape, or truncated ring-shaped disc, as only examples.

In an example, the unit layer may further include at least one or more active layers of a piezoelectric layer, a magnetoelectric layer, or a magnetostrictive layer.

In an example, the plurality of unit layers may include metal layers having the same or different thicknesses, and the plurality of unit layers may include unit layers having the same or different thicknesses.

In an example, the plurality of unit layers may be stacked in a stacked structure in which a length of the metal layer of each unit layer is continuously reduced.

In an example, the plurality of unit layers may be stacked in a stepped stacked structure in which a length of each unit layer and the length of the metal layer are continuously reduced.

In an example, the electrode may further include a single groove or a plurality of grooves with a side open. The groove may include a region, where at least a portion of the metal layer protrudes into the groove, and the region, where at least a portion of the metal layer protrudes into the groove, may have a stepped structure, in which a protruding length is continuously reduced, or may have the same protruding length.

In an example, the nanocavities may be provided in a region close to the groove, or the nanocavities may be exposed to an inner surface of the groove.

In an example, the cavities formed between the upper surface of the unit layer and the lower surface of the unit layer, facing the upper surface, may be exposed to the inner surface of the groove, and the cavities may be nanocavities or microcavities.

In an example, a device, in which a CMOS chip and the electrode of the one or more examples are integrated, is provided.

In an example, the device may be monolithically integrated or heterogeneously integrated.

In an example, the electrode of the one or more examples may lower the impedance. In some examples, the functionalization of neural probes with platinum black is among the most promising current approaches to lower electrical impedance. However, this material is electrochemically unstable, which may create several issues, such as unreproducible measurement performance, low-throughput fabrication, and unfeasibility of device reutilization. However, the electrode of the one or more examples may achieve an electrical impedance values that is comparable or lower than electrode functionalized with unstable electrochemical materials, such as platinum black.

In an example, the electrode of the one or more examples may provide a small footprint and compatibility with CMOS manufacturing. In some examples, as a “proof-of-principle device”, a 128-channel chip may be manufactured with 4-level electrode (30 channels per layer+8×GND). By stacking electrodes, the electrical impedance may be greatly reduced without enlarging the device footprint. Since the upper end and lower end surfaces of the electrode remain flat and homogeneous, preprocessing or postprocessing may be performed on the surface thereof, thereby introducing various functional layers.

In an example, mechanical stability of multi-level cavities (e.g., nanocavities) of the one or more examples may be provided.

In an example, in the electrode of the one or more examples, each unit layer may be independently controlled. In some examples, the unit layer may be independently operated or controlled by implementing each unit layer with materials according to the operations. In some examples, each level/electrode stack (e.g., the unit layer) may be independently controlled while interfacing with the same biological cell. In some examples, when an additional number of a variable is given, there are additional possibilities for current/voltage modulation. In some examples, each level may be implemented using different combinations of materials (e.g., iridium oxide, aluminum nitride, and bismuth selenide) and used for various purposes, such as current injection, voltage recording, pH measurement, and temperature sensing. The effect on the spatial resolution may be minimized, since each electrode stack remains buried under the same aperture, which is much smaller than biological cells.

In an example, in the electrode of the one or more examples, a conductive material layer (e.g., Ti) may be disposed on the upper end of the cavity (e.g., nanocavity), which may increase a contact area available for interaction with chemical species, media, gases, and the like. For example, the contact area available for interaction with electrolyte may be increased by more than two times (e.g., compared to a case where no cavities (e.g., nanocavities) are formed).

In an example, in the electrode of the one or more examples, an initial multi-level nanocavity-based device may further reduce the impedance by up to 2× (per level) through the manufacturing of the nanocavities with conductive electrode arranged on the upper end and lower end surfaces.

In an example, the electrode may provide a partially free-standing electrode stack by laterally wet-etching the insulating layer during the cavity enlargement fabrication step of minimizing a parasitic effect.

In an example, in the electrode of the one or more examples, a lateral space between the electrodes may enable cell expansion into the corresponding region, thereby increasing sealing resistance and maximizing a signal-to-noise ratio.

In an example, the CMOS-based device may be applied to arbitrary electrochemical sensing applications that benefit from impedance reduction and/or specific capacitance enhancement by the electrode of the one or more examples. In some examples, the CMOS-based device may be used as a sensing layer for real-time action potential recording of biological cells. In some examples, the CMOS-based device may be used to sense pH, glucose, triglyceride, and mRNA.

As described above, although the examples have been described with reference to the limited drawings, one of ordinary skill in the art may apply various technical modifications and variations based thereon. For example, suitable results may be achieved if the described techniques are performed in a different order and/or if components in a described system, architecture, device, or circuit are combined in a different manner and/or replaced or supplemented by other components or their equivalents.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An electrode, comprising:
at least one of a single unit layer and a plurality of stacked unit layers,
wherein each of the single unit layer or the plurality of stacked unit layers respectively comprises a single cavity or a plurality of cavities.

2. The electrode of claim 1, wherein the cavities are at least one of nanocavities and microcavities.

3. The electrode of claim 1, wherein each cavity of the single unit layer or each cavity the plurality of stacked unit layers has a height of 1 nanometer (nm) to 1000 nm, a length of 1 nm to 1 millimeter (mm), or both.

4. The electrode of claim 1, wherein, for each of the single unit layer or each unit layer of the plurality of stacked unit layers, the cavities are disposed between an upper surface of the unit layer and a lower surface of the unit layer facing the upper surface of the single unit layer.

5. The electrode of claim 1, wherein the cavities of the single unit layer or the cavities of the plurality of stacked unit layers are arranged in a row or arranged irregularly along a height direction of the electrode.

6. The electrode of claim 1, wherein the unit layer of the single unit layer or the unit layers the plurality of the plurality of stacked unit layers comprises a first insulating layer, a metal layer, and a second insulating layer.

7. The electrode of claim 6,
wherein the first insulating layer and the second insulating layer respectively comprise insulating materials, and
wherein the cavities of the single unit layer or the cavities of the plurality of stacked unit layers are formed in at least one or more portions of the metal layer, between the metal layer and the first insulating layer, or between the metal layer and the second insulating layer.

8. The electrode of claim 7, wherein at least one of a single metal layer and a plurality of metal layers is provided, and the single metal layer or the plurality of metal layers is embedded between the first insulating layer and the second insulating layer of each of the unit layer of the single unit layer or the unit layers of the plurality of stacked unit layers.

9. The electrode of claim 1, wherein the plurality of stacked unit layers is stacked to form a stepped stacked structure.

10. The electrode of claim 1, wherein the plurality of stacked unit layers is stacked such that diameters of the unit layers are continuously reduced.

11. The electrode of claim 1, wherein the plurality of stacked unit layers comprises a unit layer having at least one or more shapes of a plate shape; or a circular shape, a semi-circular shape, an elliptical shape, a ring shape, or a truncated ring-shaped disc.

12. The electrode of claim 1, wherein the unit layer further comprises at least one or more active layers of a piezoelectric layer, a magnetoelectric layer, or a magnetostrictive layer.

13. The electrode of claim 1,
wherein the plurality of stacked unit layers comprises metal layers having a same thickness or different thicknesses, and
wherein the plurality of stacked unit layers comprises unit layers having a same thickness or different thicknesses.

14. The electrode of claim 13, wherein the plurality of stacked unit layers is stacked in a stacked structure in which a length of the metal layer of each unit layer is continuously reduced.

15. The electrode of claim 13, wherein the plurality of stacked unit layers is stacked in a stepped stacked structure in which a length of each unit layer and the length of the metal layer are continuously reduced.

16. The electrode of claim 13, further comprising:
a single groove or a plurality of grooves disposed with an open side,
wherein the groove or each of the plurality of grooves comprises a region, where at least a portion of the metal layer protrudes into the groove or the plurality of grooves, and
wherein the region, where at least a portion of the metal layer protrudes into the groove or the plurality of grooves, has a stepped structure, in which a protruding length is continuously reduced, or has a same protruding length.

17. The electrode of claim 16,
wherein the single cavity or the plurality of cavities are provided in a region close to the groove or the plurality of grooves, or
wherein the single cavity or the plurality of cavities are exposed to an inner surface of the groove or the plurality of grooves.

18. The electrode of claim 17,
wherein the single cavity or the plurality of cavities formed between the upper surface of the unit layer and the lower surface of the unit layer, facing the upper surface, are exposed to the inner surface of the groove or the plurality of grooves.

19. A device, wherein a complementary metal-oxide-semiconductor (CMOS) chip and the electrode of claim 1 are integrated.

20. The device of claim 19, wherein the device is monolithically integrated or heterogeneously integrated.
